(19) United States
(12) Patent Application Publication
(10) Pub. No.: US 2026/0334155 A1
(43) Pub. Date: Oct. 22, 2026

(54) BERYLLIUM ALUMINATE BASED DIELECTRIC MATERIAL FOR SEMICONDUCTOR MANUFACTURING AND PROCESSING APPLICATIONS

(71) Applicant: WATLOW ELECTRIC MANUFACTURING COMPANY, St. Louis, MO (US)

(72) Inventors: Joaquin A. SANTILLAN, Gilbert, AZ (US); Austin STANFIELD, St. Louis, MO (US); Jason E. SMITH, O'Fallon, MO (US); Ashish BHATNAGAR, St. Louis, MO (US)

(73) Assignee: WATLOW ELECTRIC MANUFACTURING COMPANY, St. Louis, MO (US)

(21) Appl. No.: 19/712,670

(22) Filed: Jun. 18, 2026

Related U.S. Application Data
(63) Continuation of application No. PCT/US2024/060507, filed on Dec. 17, 2024.
(60) Provisional application No. 63/611,837, filed on Dec. 19, 2023.

(51) Int. Cl. H10P 72/72; C04B 35/08; C04B 35/10

(52) U.S. Cl. CPC H10P 72/722; C04B 35/08; C04B 35/10

(57) ABSTRACT

A beryllium aluminate ceramic material includes greater than 0 wt. % and up to 10 wt. % of at least one of an alkaline earth metal material, rare earth metal material, or combinations thereof, with a beryllium aluminum oxide remainder, and trace impurities. The ceramic material may include at least one of a beryllium oxide, aluminum oxide, aluminum nitride material, or combinations thereof. The ceramic material may include beryllium aluminate grains with a solid solution of at least one of the alkaline earth metal material, rare earth metal material, a boron material, a carbon material, a titanium material, a nitride material, a zirconium material, or combinations thereof.

### CROSS-REFERENCE TO RELATED APPLICATIONS

This application is a continuation of International Application No. PCT/US2024/060507, filed on Dec. 17, 2024, which claims priority to and the benefit of U.S. provisional application number 63/611,837, filed on Dec. 19, 2023. The disclosures of the above applications are incorporated herein by their reference.

### FIELD

The present disclosure relates to a beryllium oxide based ceramic material having a high thermal conductivity, high electrical resistivity, a method for manufacturing the beryllium aluminate based ceramic material, and a ceramic material and part formed by the method, particularly for a semiconductor manufacturing apparatus such as an electrostatic chuck (ESC).

### BACKGROUND

The statements in this section merely provide background information related to the present disclosure and may not constitute prior art.

In semiconductor manufacturing equipment used for dry processes (e.g., plasma coating, atomic layer deposition (ALD), chemical vapor deposition (CVD), plasma enhanced ALD (PEALD), and PECVD among others) a highly reactive halogen (e.g., Br, F or Cl) based plasma is used for etching and cleaning. Thus, members used in the semiconductor manufacturing equipment are desired to have high corrosion resistance. In general, high-corrosion resistant metals, such as anodized aluminum, nickel-based alloys sold under the trademark HASTELLOY™, stainless steels, and ceramic materials are used. Materials for electrostatic chucks and heaters, which support silicon (Si) wafers, are desired to have high corrosion resistance (low relative etching rates) and low particle emission properties.

Highly reactive halogen (e.g., F, or Cl) plasma systems employ corrosion resistant ceramic members (e.g., aluminum nitride, aluminum oxide, beryllium oxide, sapphire, silicon nitride, and various spinels, among others) to survive the long periods of exposure to the highly reactive plasma. The plasma degrades and corrodes ceramic members gradually and as a part of the degradation and corrosion, particles from the ceramic members are emitted. The higher the corrosion resistance of a material, the longer the service life of the members.

Known devices in a semiconductor manufacturing apparatus for wafer processing include electrostatic chucks (ESCs) and heaters. The electrostatic chucks (ESC) and heaters, which support Si wafers, have excellent temperature uniformity with gradients less than 5 °C. To improve the temperature uniformity, a material having high thermal conductivity is preferably used.

ESCs are generally constructed to stabilize and provide a clamping force to hold wafers (or other substrates) utilizing electrostatic forces generated by a voltage difference between the wafer and the RF electrode. The ESC clamping force secures a wafer during various dry processes including vapor deposition (e.g., PEALD) and etching, among others. Etching (e.g., dry, or wet) removes wafer layers and wafers undergo multiple etching steps during manufacture. Plasma etchers produce energetic free radicals that attack and react at the wafer surface either isotropically or anisotropically. ESCs with accurate thermal control increase processing rates and improve yields. During processing, the ESC uniformly heats (or cools) the wafer and reduces particle generation by attaching (e.g., clamping) the wafer to the ESC or processing plate. During plasma manufacturing, the ESC is worn in the harsh chemical and electrical processing chamber. Many ESCs for etching are composed of sintered alumina (Al₂O₃), with one or more electrodes embedded in the sintered alumina, and heaters composed of sintered alumina, and heaters embedded in the sintered alumina, among others. Many ESCs for deposition have transitioned from alumina to aluminum nitride.

To improve ESC thermal uniformity, ESCs are normally composed of AlN, silicon nitride (e.g., Si₃N₄), boron nitride (e.g., BN), silicon carbide (SiC) and beryllium oxide (e.g., BeO). Among these compounds, AlN has a particularly high thermal conductivity which allows high temperature uniformity in deposition and etching environments. Thus, AlN is used in the semiconductor and thermomechanical industries because of its high thermal conductivity, high plasma corrosion resistance, high volume resistivity, thermal expansion matching that of silicon, tungsten, and molybdenum, low dielectric constant, and non-toxicity, among other properties. However, beryllium aluminate has improved plasma corrosion resistance than aluminum nitride.

However, ceramic devices such as ESCs are difficult to manufacture with a variety of embedded components (e.g., electrodes, heaters, electrical terminations) which are made from different materials than the ceramic substrate. Differences in coefficients of thermal expansion (CTE) can cause premature cracking and lead to degradation in performance of the ESC. Further, manufacturing tolerances for wafer processing are extremely narrow, and thus the ESC is manufactured and operated within strict limits.

The present disclosure addresses these challenges related to the manufacture and operation of beryllium aluminate based ceramic materials and parts (e.g., ESCs) in extreme chemical and thermal environments.

### SUMMARY

This section provides a general summary of the disclosure and is not a comprehensive disclosure of its full scope or all of its features.

In one form of the present disclosure, a beryllium aluminate ceramic material is provided. The beryllium aluminate ceramic material includes greater than 0 wt. % and up to 10 wt. % of at least one of an alkaline earth metal material, rare earth metal material, or combinations thereof, a beryllium aluminum oxide remainder; and trace impurities.

In variations of this beryllium aluminate ceramic material, which may be implemented individually or in any combination: the beryllium aluminate ceramic material includes at least one of a beryllium oxide phase, aluminum oxide phase, aluminum nitride phase, or combinations thereof; the beryllium aluminate ceramic material includes trace values of at least one of aluminum oxide material, aluminum nitride material, or combinations thereof; and the beryllium aluminate ceramic material excludes at least one of aluminum oxide phase, aluminum nitride phase, or combinations thereof.

In other forms of this material, which may be implemented individually or in any combination: the beryllium aluminum oxide is at least one of BeAl₂O₄, BeAl₆O₁₀, or combinations thereof; the beryllium aluminate ceramic material includes a plurality of elongated grains, equiaxial grain microstructures, grain boundary phases, secondary phases, or combinations thereof; the beryllium aluminate ceramic material includes a plurality of an alkaline earth metal, aluminate, aluminum nitride, aluminum oxide, beryllium aluminate, beryllium aluminum oxynitride, beryllium hexaaluminate, ceylonite, chrysoberyl, garnet, nitride, oxide, oxynitride, perovskite, pleonaste, pyrochlore, rare earth metal, spinel, titanate, yttrium oxide phases, or combinations thereof, including their allomorphs or allotropes; the beryllium aluminate ceramic material includes less than 1% of at least one of the alkaline earth metal material, rare earth metal material, or combinations thereof in the beryllium aluminate ceramic material; and the beryllium aluminate ceramic material includes beryllium aluminate grains with a solid solution of at least one of an alkaline earth metal-based material, a rare earth metal-based material, a boron-based material, a carbon-based material, a nitride-based material, a titanium-based material, a zirconium-based material, or combinations thereof.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is an exemplary process diagram, according to the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

The present disclosure provides a ceramic material composition having corrosion resistance against harsh chemical environments, such as halogen-based plasma. Further, the ceramic material composition has a similar linear thermal expansion coefficient of tungsten or molybdenum and meets high temperature thermal conductivity and volume resistivity requirements up to at least 650 °C for equipment in wafer production, i.e., ion implantation, deposition, cleaning, and etching.

Generally, a ceramic material and/or part of the present disclosure comprises a beryllium aluminate ceramic. The beryllium aluminate ceramic comprises greater than 0 wt. % and up to 10 wt. % of at least one of an alkaline earth metal material, rare earth metal material, or combinations thereof, a beryllium aluminum oxide remainder, and trace impurities.

### Ceramic Mixture

Alkaline earth metals and/or compounds are provided in amounts greater than 0 wt. % and up to 10 wt. % as a sintering aid, improving at least the wettability between the constituents of the ceramic mixture. Alkaline earth metal oxides combine with excess oxygen, aluminum oxide, and other impurities from the constituent ceramic mixture to create aluminates, ceylonites, dioxides, garnets, monoxides, nitrides, oxides, oxynitrides, perovskites, and pleonastes, spinels, and their applicable inverse and/or reordered configurations (allomorphs and allotropes). When the alkaline earth metal oxides are less than 0.05 wt. %, the alkaline earth metal oxide becomes less effective. When the alkaline earth metal oxide is greater than 10 wt. %, the alkaline earth metal oxide does not provide the desired combination corrosion resistance, dielectric constant, dielectric strength, resistivity, strength, thermal conductivity, and thermal expansion.

Aluminum nitride (e.g., AlN) has a sufficient combination of corrosion resistance, strength, thermal conductivity (theoretically≈320 W/mK), thermal expansion, and volume resistivity in many reactive plasma manufacturing environments, thus making AlN an economical base material for applications in many highly reactive plasma environments (<650 °C). Aluminum nitride has a lower volume resistivity, density, melting point and other properties than beryllium compounds (e.g., BeAl₂O₄, BeO); rendering AlN, currently, less desirable and/or unsuitable than beryllium compounds for plasma at higher temperatures (>650 °C) due to AlN's lower plasma environment service life for the manufacturing loads and capacities at these higher temperatures. The inventors have discovered that aluminum nitride readily absorbs, integrates, or coexists with yttrium oxide, beryllates, aluminates, and corresponding oxides, nitrides, oxynitrides, their complex oxides, and oxynitrides, and their applicable or reordered configurations (allomorphs and allotropes). The incorporation of other elements and compounds improves the thermodynamic properties of the resultant material rendering the resultant material less reactive within service environments. Aluminum nitride is present at trace levels from the constituent materials. The constituent materials are alkaline earth metals, beryllium aluminum oxides, rare earth metals, and/or accompanying trace elements.

Aluminum oxide (e.g., Al₂O₃, Al₂O, and AlO among others) improves at least one of the densification, wettability between the constituents of the ceramic mixture, and/or the volume resistivity of the ceramic material and part. Aluminum oxide has a lower volume resistivity, melting point, and other properties than beryllium compounds (e.g., BeAl₂O₄, BeAl₆O₁₀, BeO) rendering the aluminum oxide, currently, less desirable and/or unsuitable than beryllium compounds for higher temperature (>650 °C) plasma due to aluminum oxide's lower plasma environment service life for the manufacturing loads and capacities at these temperatures. Aluminum oxide may be added to promote the in situ formation of beryllium aluminates and/or is present at trace levels from the constituent materials.

Beryllium aluminum oxides (e.g., BeAl₂O₄, BeAl₆O₁₀, and BeAlON among others, including allomorphs and allotropes), have improved thermal performance and corrosion resistance as compared to aluminum nitride in highly reactive plasma manufacturing environments. The beryllium aluminum oxides (e.g., BeAl₂O₄, BeAl₆O₁₀, and BeAlON) are provided in an amount up to 100 wt. % and in some forms greater than 0 wt. % and less than 100 wt. %. Beryllium aluminates have an up to 20% reduction in their coefficient of thermal expansion (CTE) as compared to magnesium aluminum oxide spinel (i.e., MgAl₂O₄). Beryllium aluminates have a CTE closer to that of silicon, silicon oxides, and aluminum nitrides than magnesium aluminum oxide spinel, reducing CTE mismatch issues with those materials. These beryllium aluminate material properties reduce the contact stresses during wafer thermal cycling (e.g., heating and cooling rates) as well as reducing electrostatic chuck bond stresses during thermal cycling thus increasing the frequency and complexity of thermal cycles. Further, beryllium aluminates have an up to 10% increase in relative permittivity as compared to magnesium aluminum oxide spinel. Higher relative permittivity increases the applied electrostatic chucking force applied to a wafer at a given electric potential in certain applications. As the electrostatic chucking force increases, the chucking efficiency increases enabling chucking at higher temperatures where dielectric losses are higher. Moreover, beryllium aluminates have increased thermal conductivity as compared to magnesium aluminum oxides. Higher thermal conductivity improves heat transfer rates and the uniformity of wafer heating; improved temperature uniformity promotes consistent and controlled deposition and etching (i.e., improves fidelity and complexity of deposition and etching process). Beryllium oxide is substitutable for some of the beryllium aluminum oxide (e.g., for in situ beryllium aluminum oxide formation during processing). Beryllium aluminate and beryllium aluminum oxide are synonyms.

Boron forms several compounds with alkaline earth metals (e.g., beryllium, Ca₃B₂N₄), aluminum, nitrogen, oxygen, rare earth metals (e.g. cerium, yttrium, among others), and zirconium that are present at temperatures up to 2100 °C and reducing the amount of boron present improves the volume resistivity of the beryllium aluminate ceramic material and part. Boron forms AlB₂ with graphite-like sheets of boron sandwiching (e.g., nestling) planes of metallically bonded aluminum and/or magnesium atoms. The metallic bonding of the aluminum and/or magnesium planes results in high electrical conductivity. Thus, by reducing or removing the introduction of boron the volume resistivity of the beryllium aluminate part is improved. Boron (e.g., BN) crucibles and ball mills are the main source of boron and thus the presence of boron and/or its compounds within the beryllium aluminate-based material is merely incidental. In other words, boron is not an intentional compositional/constituent element.

Molybdenum forms several compounds with alkaline earth metals (e.g., beryllium), aluminum, boron, nitrogen, oxygen, rare earth metals (e.g., cerium, yttrium, among others), and zirconium (e.g., MoN, MoO₃, MoS₂, Y₂MoO₁₂, Y₂MoO₆, Y₄MoO₉, and Y₆MoO₁₂ among others, including their allomorphs and allotropes) depending on at least composition, pressure, and temperature. Molybdenum also combines with the impurities from the constituent ceramic mixture to create one or more aluminate, ceylonite, chrysoberyl, garnet, nitride, oxide, oxynitride, perovskite, pleonaste, pyrochlore, spinel, and their allomorphs and allotropes, depending on at least composition, pressure, and temperature. Molybdenum is often present in electrical components (e.g., electrodes, heating elements, RF antennas) embedded within the beryllium aluminate-based material, or is a material used in mixing crucibles, and thus the presence of molybdenum and/or its compounds within the beryllium aluminate-based material is merely incidental. In other words, molybdenum is not an intentional compositional/constituent element.

Platinum forms several compounds with alkaline earth metals (e.g., beryllium, Ba₄PtO₆, CaPtO₃, Ca₄PtO₆), aluminum, boron, nitrogen, oxygen, rare earth metals (e.g., cerium, Eu₂Pt₇, yttrium, among others), and zirconium depending on at least composition, pressure, and temperature. Platinum also combines with the impurities from the constituent ceramic mixture to create one or more aluminate, ceylonite, chrysoberyl, garnet, oxide, perovskite, pleonaste, pyrochlore, spinel, and their allomorphs and allotropes, depending on at least composition, pressure, and temperature. Platinum crucibles are the main source of platinum and thus the presence of platinum and/or its compounds within the beryllium aluminate-based material is merely incidental. In other words, platinum is not an intentional compositional/constituent element.

Rare earth metal oxides (e.g., lanthanide, Sc, and Y oxides, or combinations thereof) are provided in an amount greater than 0 wt. % and up to 10 wt. % as a sintering aid, improving at least the wettability between the constituents of the ceramic mixture. Rare earth metal oxides combine with excess oxygen, aluminum oxide, and other impurities from the constituent ceramic mixture to create aluminates, ceylonites, dioxides, garnets, monoxides, nitrides, oxides, oxynitrides, perovskites, and pleonastes, spinels, and their applicable inverse and/or reordered configurations. When the rare earth metal oxides are less than 0.05 wt. %, the rare earth metal oxide becomes less effective. When the rare earth metal oxide is greater than 10 wt. %, the rare earth metal oxide does not provide the desired combination corrosion resistance, dielectric constant, dielectric strength, resistivity, strength, thermal conductivity, and thermal expansion. The lanthanides are the “true” rare earth metals. However, scandium and yttrium are considered rare earth elements (within the art and thus the present disclosure), because they tend to share the same ore deposits as lanthanides and exhibit similar chemical properties. These rare earth metals are substitutable with each other to some degree.

Refractory and transition metals (e.g., Co, Cr, Hf, Ir, Ni, Os, Rh, Ru, Ti, V, Zr, or combinations thereof) and/or compounds in amounts greater than 0 wt. % and up to 10 wt. %. these refractory and transition metals combine with the impurities from the constituent ceramic mixture to create one or more aluminate, ceylonite, chrysoberyl, garnet, nitride, oxide, oxynitride, perovskite, pleonaste, pyrochlore, spinel, and their allomorphs and allotropes, depending on at least composition, pressure, and temperature. Refractory and transition metals are often present as trace elements from the constituent materials or embedded electrical components, and thus the presence of unspecified refractory and/or transition metals and their compounds within the beryllium aluminate-based material is merely incidental. In other words, unspecified refractory and/or transition metals are not an intentional compositional/constituent element.

Titanium oxide (e.g., TiO, TiO₂, and Ti₂O₃, among others) improves at least one of the coefficient of thermal expansion, corrosion resistance, density, dielectric constant, electrical resistance, melting/sintering temperature, strength, thermal conductivity, and/or wettability of the ceramic mixture or part in the desired environments (e.g., formation and service among others). Titanium also combines with oxygen and oxides from the aluminum nitride, aluminum oxide, beryllium aluminum oxide, boron, yttrium, zirconium, and other impurities from the constituent ceramic mixture to create one or more aluminate, ceylonite, chrysoberyl, garnet, nitride, oxide, oxynitride, perovskite, pleonaste, pyrochlore, spinel, titanate, and their allomorphs and allotropes, depending on at least composition, pressure, and temperature. Titanium is often present as trace elements from the constituent materials or embedded electrical components, and thus the presence of titanium and its compounds within the beryllium aluminate-based material is merely incidental. In other words, titanium is not an intentional compositional/constituent element.

Yttrium oxide (e.g., YO, YO₂, Y₂O₃) is provided in an amount greater than 0 wt. % and up to 10 wt. % as a sintering aid, improving at least the wettability between the constituents of the ceramic mixture. Yttrium oxide combines with excess oxygen, aluminum oxide, and other impurities from the constituent ceramic mixture to create aluminates, ceylonites, dioxides, garnets, monoxides, nitrides, oxides, oxynitrides, perovskites, and pleonastes, spinels, and their applicable inverse and/or reordered configurations. When the yttrium oxide is less than 0.05 wt. %, the yttrium oxide becomes less effective. When the yttrium oxide is greater than 10 wt. %, the yttrium oxide does not provide the desired combination corrosion resistance, dielectric constant, dielectric strength, resistivity, strength, thermal conductivity, and thermal expansion. Yttrium is substitutable with other rare earth metals.

Zirconium oxide (e.g., Zr₂O₃, ZrO₂, ZrO) is available in amounts up to 4.5 wt. %, improving at least the wettability between the constituents of the ceramic mixture and the coefficient of thermal expansion or the dielectric constant. Zirconium oxide is mostly present as an impurity from the ball mill media, and thus the presence of zirconium oxide and/or its compounds within the beryllium aluminate-based material is merely incidental. In other words, zirconium oxide is not an intentional compositional/constituent element.

### Ceramic Part and Microstructure

The process described below can form ceramic materials and parts with aluminates, chrysoberyls, nitrides, oxides, spinels, including their allomorphs and allotropes and other phases across their microstructure. The beryllium aluminum oxides include all thermodynamically stable, partial thermodynamically stable, and non-thermodynamically stable phases amount the systems of beryllium, aluminum, oxygen, and nitrogen such as Be_{y}Al_{3-y-1/3x}Q_{2/3x}O_{3+x+y}N_{1-x-y} where Q is a vacancy on a cation site for x>8 and a cation interstitial for x<8, and stochiometric crystal for x=8. These phases are collectively referred to as BeAlON. Further, cation doping with transition metals and lanthanide series elements improves optical properties. A common dopant in BeAl₂O₄ is Cr3+ the combination of which is alexandrite. Alexandrite has interesting optical properties. Cation doping of beryllium aluminate and beryllium hexaaluminate is also within the scope of the present disclosure.

### Ceramic Preform/Test Specimen Formation

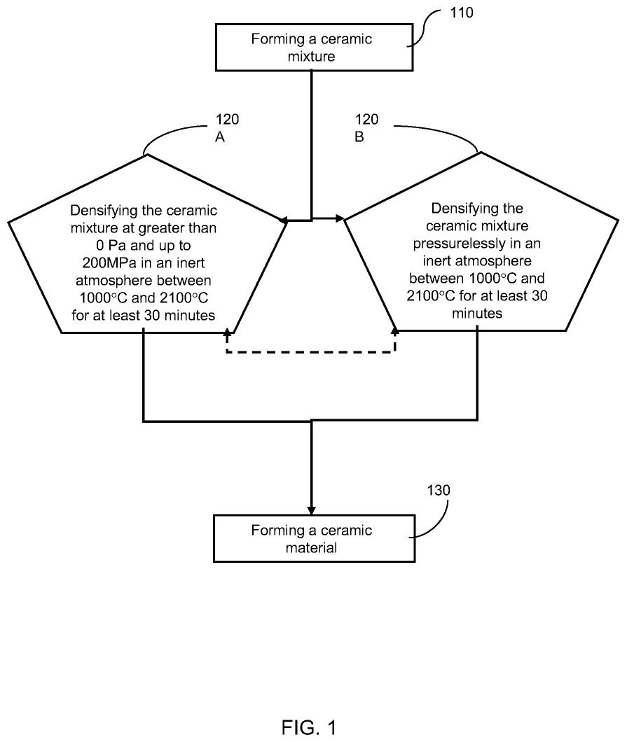

Powders of beryllium aluminum oxide (average particle size ≲1 micron), calcium oxide, magnesium oxide, and yttrium oxide (average particle size ≲1 micron) were used as raw materials. A ceramic mixture (see FIG. 1, 110) of beryllium aluminum oxide and at least one of an alkaline earth metal compound, a rare earth metal compound, or combinations thereof were prepared according to the ranges set forth above. The ceramic mixture includes any allomorphs, allotropes, or impurities from the constituent materials and/or processing components.

The ceramic mixture particle size was reduced (e.g., milled, comminuted, among others) with high purity ceramic ball media (e.g., aluminum nitride, aluminum oxide, and zirconium oxide among others) in a ceramic lined container in isopropyl alcohol for at least 30 minutes and up to 36 hours. After reduction, the powders of the ceramic mixture have average particle size ranges of: d10≈0.20 micron; <d50≈1.70 micron; and <d90≈2.4 micron. Upon discharge from the reducer, an acrylic binder is added to the ceramic mixture in an amount of less than 4.5% of the total weight percent of the total ceramic mixture and mechanically mixed with a laboratory stirrer for at least one hour.

The inventors have also discovered that if prior to sintering/densification of the ceramic mixture, an additional particle size reduction (e.g., second, third, and so forth resulting in D50: 0.6-1.5 micron) is performed, there can be an improvement in the desired combination of corrosion resistance, density, dielectric constant, dielectric loss, dielectric strength, hardness, plasma etch rates, volume resistivity, strength, thermal conductivity, and thermal expansion of the sintered composite in the desired manufacturing environments.

After mechanical mixing, the bound ceramic mixture is agitated to prevent sedimentation and then spray dried to produce homogeneous and spherical granules. In one form the ceramic mixture is sprayed under flowing nitrogen (i.e., inert gas) at temperatures between 45 °C and up to 175 °C. The spray dried granules are compacted into about 15 mm diameter×5 mm thick green disks by uniaxial die pressing at about 10 MPa. The green disks form test specimens. The test specimens (e.g., ceramic preforms) are placed in a high purity crucible (e.g., boron nitride, molybdenum, and platinum among others), surrounded by packing powder, sintered/thermally treated, and purified. Densification (e.g., sintering; see FIG. 1; 120A and 120B) is conducted in a resistive element furnace (e.g., graphite, molybdenum, or tungsten among others) between at least 1000 °C and up to at least 2100 °C for at least 15 minutes and up to 40 hours under flowing gases (e.g., carbon, nitrogen, oxygen, and sintering atmospheres among others and combinations thereof) at up to about 150 ksi (1 GPa; see FIG. 1; 120A and 120B) over atmospheric pressure and forms the ceramic material (130)/test specimen. In some instances, the process includes consolidating the ceramic mixture to form a ceramic preform prior to densifying the ceramic mixture.

Thermal treatment (heat treatment) involves heating and/or cooling materials, normally to extreme temperatures, to achieve the desired result such as forming, hardening, or softening of the material. Briefly, and non-limitingly heat, treatment techniques include annealing, case hardening, normalizing, quenching, and stress relaxation. Annealing heats or cools the material to relieve internal stresses present in the material due to forming processes and to form desired microstructures through thermodynamic and kinetic processes. Case hardening diffuses an element into the surface layers of another material. Normalizing provides at least one of a uniform composition, uniform grain/crystal size, uniform properties, and/or stress relaxation throughout a material by holding the material at a constant temperature. Quenching cools the material at a rapid rate to maintain properties and structures usually only present at elevated temperatures. Stress relaxation or stress relieving reduces the internal stresses of a material. The individual techniques are performable multiple times and in various orders during a thermal cycle to acquire the desired material properties. For example, annealing at a first temperature, holding the first temperature constant, annealing at a second temperature, stress relaxation for an hour, annealing at a third temperature, case hardening, cooling to a fourth temperature, quenching to a fifth temperature, and normalizing at the fifth temperature. It should be understood herein that thermal hold duration and the rate of cooling, heating, and/or quenching are thermal treatments.

The process described above is also implemented to form ceramic parts (FIG. 1, 130) that comprise: grain sizes less than or equal to 5 micron and grain sizes less than and/or equal to 3 micron; and relative densities of at least 95%, at least 99%, at least 90% and less than 99.5%, and/or at least 90% and less than 100.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

Various compositions/elements of the present disclosure may be presented in a range format, which should not be construed as limiting the scope of the present disclosure. The description of a range should be considered to have specifically disclosed all the possible subranges as well as individual numerical values within that range. For example, description of a range such as from 1 to 10 should be considered to have specifically disclosed subranges such as, by way of example, from 1 to 5, from 2 to 7, from 1 to 9, from 3 to 4, and so on, as well as individual target values within the range, for example, 1, 2, 3, 4, 5, and 6, among others. Therefore, the disclosure of a given range should be construed to include all values within the range even if not explicitly recited.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A beryllium aluminate ceramic material comprising:
greater than 0 wt. % and up to 10 wt. % of at least one of an alkaline earth metal material, a rare earth metal material, or combinations thereof;
a beryllium aluminum oxide remainder; and
trace impurities.

2. The beryllium aluminate ceramic material of claim 1, wherein the beryllium aluminate ceramic material has at least one of a beryllium oxide phase, an aluminum oxide phase, or an aluminum nitride phase.

3. The beryllium aluminate ceramic material of claim 1, wherein the beryllium aluminum oxide remainder comprises at least one of BeAl₂O₄ or BeAl₆O₁₀.

4. The beryllium aluminate ceramic material of claim 1, wherein the beryllium aluminate ceramic material has a microstructure having a plurality of elongated grains or equiaxial grains.

5. The beryllium aluminate ceramic material of claim 1, wherein the at least one of the alkaline earth metal material, rare earth metal material, or combinations thereof is less than 1 wt. %.

6. The beryllium aluminate ceramic material of claim 1, wherein the beryllium aluminate ceramic material comprises beryllium aluminate grains with a solid solution of at least one of an alkaline earth metal-based material, a rare earth metal-based material, a boron-based material, a carbon-based material, a nitride-based material, a titanium-based material, a zirconium-based material, or combinations thereof.

7. A part comprising the beryllium aluminate ceramic material of claim 1.

8. The part of claim 7, wherein the part is an electrostatic chuck.

9. A beryllium aluminate ceramic material comprising:
greater than 0 wt. % and up to 10 wt. % of at least one of an alkaline earth metal material, a rare earth metal material, or combinations thereof;
a beryllium aluminum oxide remainder; and
trace impurities,
wherein the beryllium aluminum oxide remainder comprises at least one of BeAl₂O₄ or BeAl₆O₁₀.

10. The beryllium aluminate ceramic material of claim 9, wherein the beryllium aluminate ceramic material has at least one of a beryllium oxide phase, an aluminum oxide phase, or an aluminum nitride phase.

11. The beryllium aluminate ceramic material of claim 9, wherein the beryllium aluminate ceramic material has a microstructure having a plurality of elongated grains or equiaxial grains.

12. The beryllium aluminate ceramic material of claim 9, wherein the at least one of the alkaline earth metal material, rare earth metal material, or combinations thereof is less than 1%.

13. The beryllium aluminate ceramic material of claim 9, wherein the beryllium aluminate ceramic material comprises beryllium aluminate grains with a solid solution of at least one of an alkaline earth metal-based material, a rare earth metal-based material, a boron-based material, a carbon-based material, a nitride-based material, a titanium-based material, a zirconium-based material, or combinations thereof.

14. A part comprising the beryllium aluminate ceramic material of claim 9.

15. A semiconductor manufacturing component comprising:
a body comprising a beryllium aluminate ceramic material, the beryllium aluminate ceramic material comprising:
greater than 0 wt. % and up to 10 wt. % of at least one of an alkaline earth metal material, a rare earth metal material, or combinations thereof;
a beryllium aluminum oxide remainder; and
trace impurities.

16. The semiconductor manufacturing component of claim 15, wherein the semiconductor manufacturing component is an electrostatic chuck.

17. The semiconductor manufacturing component of claim 15, wherein the beryllium aluminum oxide remainder comprises at least one of BeAl₂O₄ or BeAl₆O₁₀.

18. The semiconductor manufacturing component of claim 15, wherein the beryllium aluminate ceramic material comprises at least one of a beryllium oxide phase, an aluminum oxide phase, or an aluminum nitride phase.

19. The semiconductor manufacturing component of claim 15, wherein the beryllium aluminate ceramic material has a grain size less than or equal to 5 microns.

20. The semiconductor manufacturing component of claim 15, wherein the beryllium aluminate ceramic material comprises beryllium aluminate grains with a solid solution of at least one of an alkaline earth metal-based material, a rare earth metal-based material, a boron-based material, a carbon-based material, a nitride-based material, a titanium-based material, a zirconium-based material, or combinations thereof.
